(19) United States
(12) Patent Application Publication
(10) Pub. No.: US 2005/0205411 A1
(43) Pub. Date: Sep. 22, 2005

(54) [PHYSICAL VAPOR DEPOSITION PROCESS AND APPARATUS THEREFOR]

(76) Inventors: Tai-Yuan Chen, Changhua County (TW); Len Mei, Milpitas, CA (US)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,698

(22) Filed: Jul. 29, 2004

(30) Foreign Application Priority Data
Mar. 19, 2004 (TW) 93107410

(51) Int. Cl. C23C 14/35

(52) U.S. Cl. 204/192.12; 204/298.19; 204/298.2

(57) ABSTRACT

A physical vapor deposition apparatus is provided. The physical vapor deposition apparatus comprises: a reaction chamber; and an electromagnet magnetron device disposed above and outside said reaction chamber, wherein when performing a physical vapor deposition process, the magnetic poles of said electromagnet magnetron device are reversed in-situ to reduce the possibility of asymmetric deposition of the thin film on the sidewalls of the opening.

### CROSS REFERENCE TO RELATED APPLICATIONS

This application claims the priority benefit of Taiwan application serial no. 93107410, filed Mar. 19, 2004.

### BACKGROUND OF INVENTION

1. Field of the Invention

This invention generally relates to a semiconductor manufacturing process and an apparatus therefor, and more particularly to a physical vapor deposition (PVD) process and an apparatus therefor.

2. Description of Related Art

In the semiconductor manufacturing processes, thin films can be formed by performing a physical vapor deposition (PVD) process or a chemical vapor deposition (CVD) process. The PVD process can be classified into evaporation and the sputtering. The evaporation process is to heat the evaporation source and use the saturated evaporation pressure to deposit the thin film. The sputter process uses the plasma to perform the ion bombardment on the target so that the atoms on the target will be sputtered. The sputtered atoms then will be deposited on the substrate to form the thin film.

It should be noted that during the sputtering process, the plasma gas generated is directly related to the generation of the plasma ionized gases (e.g., the Argon ionized gases); i.e., the collision of the electrons with high energy and the plasma atom gases will significantly affect the sputtering process. Hence, to increase the ionization of the plasma atom gases (so-called the sputtering yield), the better way is to extend the traveling distance of the electrons before the electrons disappear in the plasma. Currently the widely adopted method is the magnetron sputtering method, which adds a magnetron device above the target in the chamber to affect the movement of the charged particles so that the particles will deflect from the original paths and moves spirally. By using the magnetron device, the possibility of the ionization of the plasma atom gases can be significantly enhanced in order to increase the sputtering yield. The increase of the sputtering yield can lower the vacuum level to a lower level than that of the traditional DC plasma, which can further control the characteristics of the deposited thin film.

However, although the magnetron device increases the possibility of the ionization of the plasma atom gases, the paths of these ionized plasma gases to the target has been affected by the magnetic field due to the magnetron device. Hence, it causes the asymmetrical deposition as shown in FIG. 1. FIG. 1 illustrates that traditional the magnetron device performs DC sputtering process to form a thin film in the opening of the alignment mark or the overlap mark on the wafer. As shown in FIG. 1, because the magnetic field generated by the magnetron field will make the ionized plasma gases move spirally and thus affects the sputtering angles of the ionized plasma gases to the target, the thin film 102 deposited on the wafer 100 will have an asymmetrical deposition at the side wall of the opening 104. Further, the thin film shift due to the asymmetrical deposition in different position of the wafer 100 would be different. I.e., the spiral movement of the ionized plasma gases will cause the rotation shift (as shown in 106 of FIG. 1) on the thin film 102 deposited on the wafer 100.

In addition, the aluminum conductive line process of the interconnect process can be performed by the magnetron DC sputtering process. To make sure that the aluminum conductive line is aligned with the contact window, after the aluminum conductive line material layer is deposited on the wafer, the measure and comparison of the alignment mark composed of the aluminum conductive line material layer in the opening and the patterned photoresistor layer for defining the aluminum conducting line will be perform, in order to make sure that the aluminum conductive line is previously aligned with the contact window or plug in the lower layer. If there is a shift, a compensation will be performed at the next exposure step of the photoresistor layer for defining the aluminum conducting line. Because the measure of the alignment mark or the overlap mark depends on the brightness due to the step height difference of the alignment mark or the overlap mark, if there is any asymmetrical metal deposition at the side walls of the opening, the center obtained based on the step height difference of the opening will be shifted. However, the asymmetrical metal deposition is caused by the magnetic field generated by the magnetron field. But the magnetron field is required to increase the sputter yield, the means to resolve the asymmetrical metal deposition is limited. Currently, although the semiconductor industry may resolve the shift issue in the photolithographic process by adjusting the process parameters, the shift of each deposition equipment is different from the other, it is not an effective way to resolve this problem.

### SUMMARY OF INVENTION

The present invention is directed to a PVD apparatus capable of depositing symmetrical thin film on the sidewall of the opening.

The present invention is directed to a PVD process for depositing symmetrical thin film on the sidewall of the opening.

According to an embodiment of the present invention, a continuous rotating magnetic device is utilized for achieving symmetrical deposition of the thin film on the sidewall of the opening.

According to an embodiment of the present invention, a physical vapor deposition apparatus comprises a reaction chamber and an electromagnet magnetron device disposed above and outside said reaction chamber. When performing a physical vapor deposition process in-situ, magnetic poles of said electromagnet magnetron device being reversed.

According to an embodiment of the present invention, a physical vapor deposition process is provided. A chamber is provided. An electromagnet magnetron device is disposed above and outside the reaction chamber. Next, the electromagnet magnetron device is activated to perform a first deposition process. The magnet poles of said electromagnet magnetron device are reversed and a second deposition process is performed to deposit a thin film.

Because in the second deposition process the magnetic poles of the electromagnet magnetron device are reversed in-situ to reverse the shift direction of the asymmetric deposition of the thin film, the possibility of asymmetric deposition of the thin film on the sidewalls of the opening can be effectively reduced.

According to an embodiment of the present invention, the physical vapor deposition apparatus comprises a reaction chamber and a rotating magnetron device disposed above and outside said reaction chamber. The rotating magnetron device comprises at least two magnet sets, wherein magnet sets are axially-symmetric or planarly-symmetric and the magnetic pole of said the magnet sets are disposed opposite each other.

According to an embodiment of the present invention, the physical vapor deposition process is provided. A chamber is provided. A rotating magnetron device is disposed above and outside said reaction chamber. The rotating magnetron device comprises at least two magnet sets, wherein the magnet sets are set axially-symmetric or planarly-symmetric and the magnetic poles of the magnet sets are disposed opposite to each other. The rotating magnetron device is activated and a deposition process is carried out. The rotating magnetron device is rotated during the deposition process.

Because during the deposition process the rotating magnetron device is rotated to rotate the shift direction of the asymmetric deposition of the thin film, the asymmetric deposition of the thin film on the sidewalls of the opening can be effectively reduced.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF DRAWINGS

FIG. 1 illustrates a traditional magnetron device performing DC sputtering process to form a thin film in an opening in the alignment mark or the overlap mark on a wafer.

FIG. 2A is a cross-sectional view of a PVD apparatus in accordance with a first embodiment of the present invention.

FIG. 2B is a cross-sectional view of a PVD apparatus when the PVD apparatus of FIG. 2A performs a PVD process.

FIGS. 3A and 3B show cross-sectional views of a PVD process to form the thin film in the opening of the alignment mark or the overlap mark on the wafer in accordance with the first embodiment of the present invention.

FIG. 4 is a top view of a electromagnet magnetron device of FIG. 2A.

FIG. 5 is a cross-sectional view of a PVD apparatus in accordance with a second embodiment of the present invention.

FIGS. 6A and 6B show cross-sectional views of a PVD process to form the thin film in the opening of the alignment mark or the overlap mark on the wafer in accordance with the second embodiment of the present invention.

FIG. 7A is a cross-sectional view of a PVD apparatus in accordance with a third embodiment of the present invention.

FIG. 7B is a cross-sectional view of the PVD apparatus when the PVD apparatus of FIG. 7A performs a PVD process.

FIGS. 8A and 8B show cross-sectional views of a PVD process to form the thin film in the opening of the alignment mark or the overlap mark on the wafer in accordance with the third embodiment of the present invention.

FIGS. 9A-9D show top views of the rotating magnetron device, wherein FIG. 9A is a top view of the rotating magnetron device of FIG. 5A, and FIG. 9B is a top view of the rotating magnetron device of FIG. 7A.

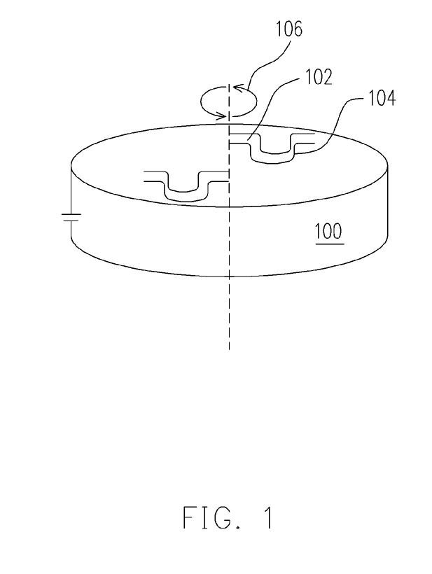

### DETAILED DESCRIPTION

In the following embodiments, the first magnetic pole is the N pole and the second magnetic pole is the S pole. One skilled in the art will understand that by changing the first magnetic pole to S pole and the second magnetic pole to N pole, the objective of the present invention can still be achieved. Therefore, the other embodiments with the opposite magnetic poles will be omitted.

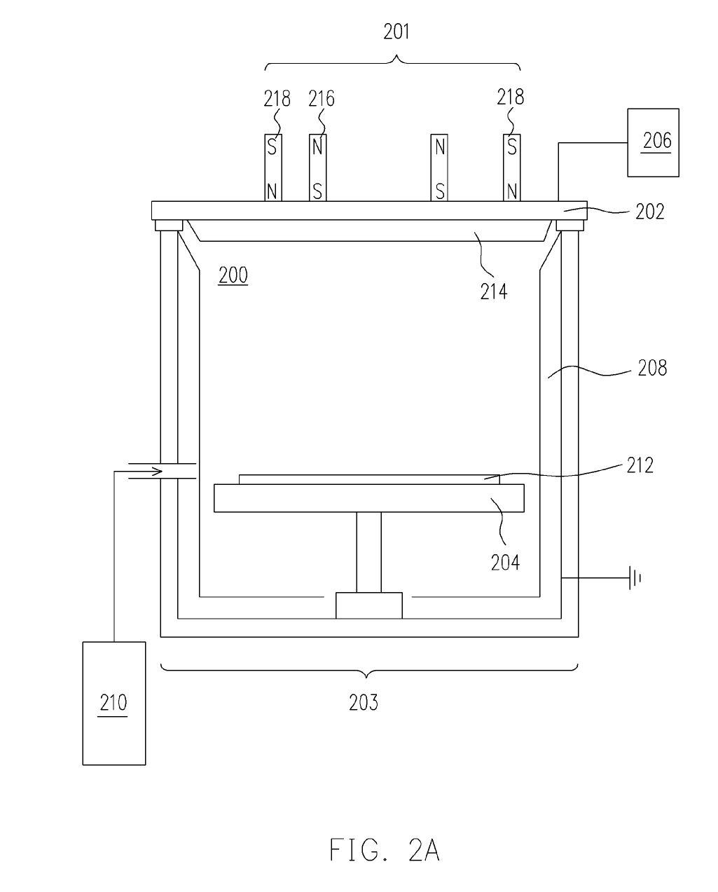

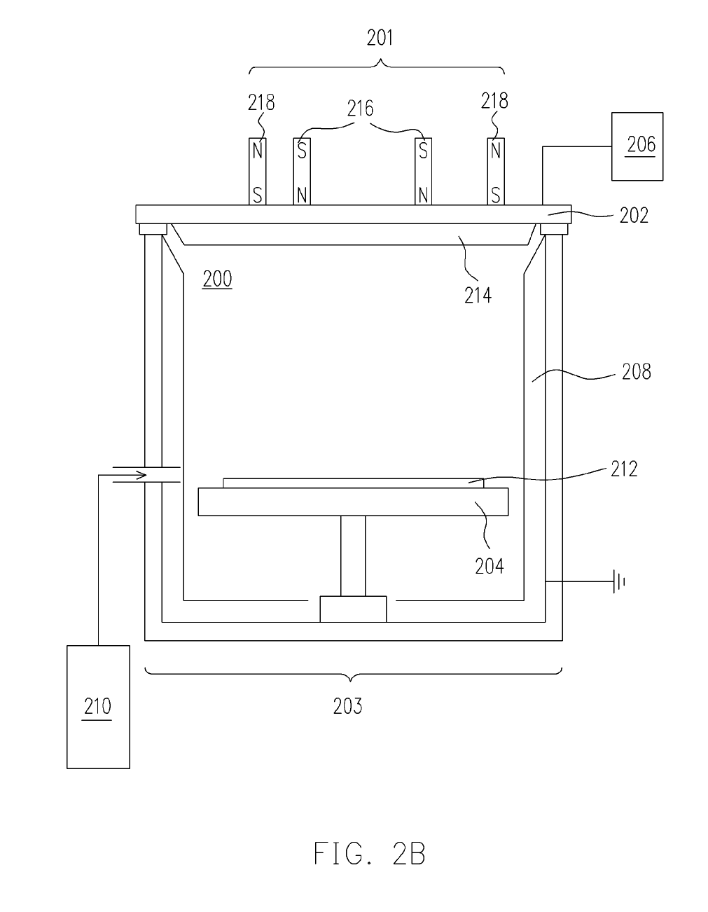

FIG. 2A is a cross-sectional view of a PVD apparatus in accordance with a first embodiment of the present invention.

Referring to FIG. 2A, the PVD apparatus includes a reaction chamber 203 and an electromagnet magnetron device 201. The reaction chamber 203 includes a chamber 200, a target backboard 202, a platen 204 for holding a wafer, a power supply 206, a cover mask 208 and a gas supply device 210.

The cover mask 208 is disposed on the sidewalls and the bottom of the chamber 200 but is not connected to the platen 204. In an embodiment, the cover mask works as an anode and is grounded. The platen 204 is at the bottom of the chamber 200 for holding the wafer 212.

The target backboard 202 is disposed at the top of the chamber 200 for holding the target 214, and is electrically connected to the power supply 206. In an embodiment, the target backboard 202 works as a cathode. The target 214 for example is metal such as Ti, Co. Ni, Ta, W, Al, and Cu.

In addition, the gas supply device 210 is connected to the sidewall of the chamber 200 to supply the plasma gases into the chamber 200. The plasma gases can be the inert gases such as Argon. In another embodiment, the chamber 200 is further connected to another gas supply device (not shown) to supply the reaction gases into the chamber 200 and the type of the reaction gases depends on the process. For example, to deposit the TiN thin film, the target 214 is Ti and the reaction gas is N₂.

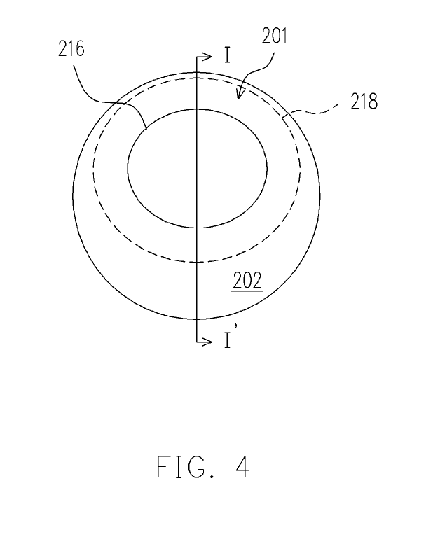

Further, the electromagnet magnetron device 201 is disposed outside the chamber 200 and is above the target backboard 202. FIG. 4 is the top view of the electromagnet magnetron device 201. The electromagnet magnetron device 201 in FIG. 2A is the cross-sectional view of the electromagnet magnetron device 201 of FIG. 4 along the I-I′ line. In this embodiment, the electromagnet magnetron device 201 includes two ring-like closed-loop electromagnets 216 and 218. In this embodiment, when a current is inputted into the electromagnet magnetron device 201, the N pole of the electromagnet 216 is directed upward (the S pole is directed downward), and the N pole of the electromagnet 218 is directed downward (the S pole is directed upward). It should be noted that the magnetic pole of the electromagnet magnetron device 201 depends on the current direction. Hence, if during the PVD process the current direction of electromagnet magnetron device 201 is reversed, the magnetic poles of the electromagnet magnetron device 201 will be reversed in-situ so that the shift direction of the thin film during the PVD process will be reversed in order to reduce the possibility of the asymmetric deposition on the sidewall of the opening.

The PVD process using the above PVD apparatus will be described as follows.

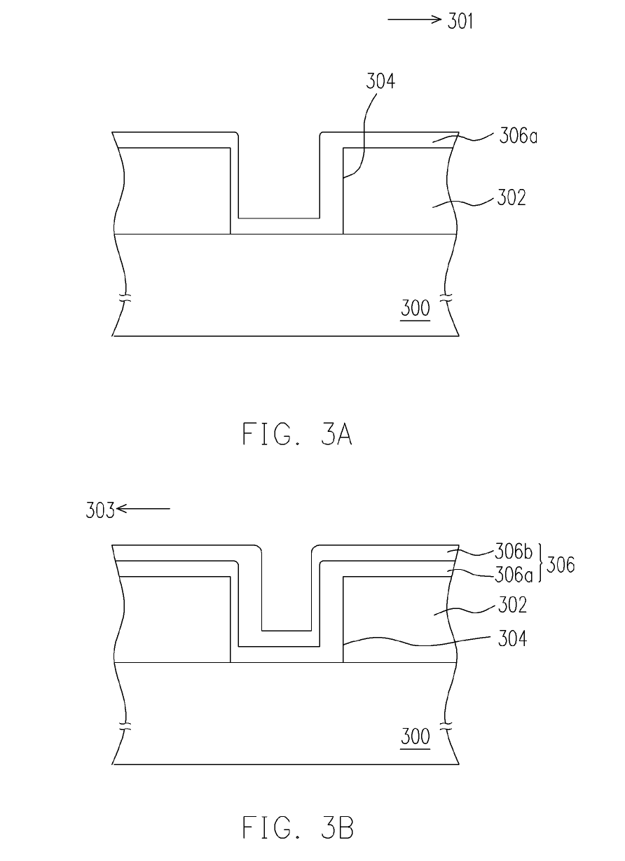

Referring to FIG. 2A, the wafer 212 is disposed on the plate 204 in the chamber 200 for depositing the thin film on the surface of the wafer 212. FIG. 3A shows the cross-sectional view of the PVD process to form the thin film in the opening of the alignment mark or the overlap mark on the wafer in accordance with the first embodiment of the present invention. The alignment mark or the overlap mark includes the Si-substrate 300 and the dielectric layer 302 on the substrate 300, and the dielectric layer 302 has an opening 304 therein.

Then a first deposition process is performed on the wafer 212. The electromagnet magnetron device 201 and the power supply 210 are activated. Next, applying a negative voltage is applied on the target backboard (cathode) 202, and the cover mask 208 is connected to a ground terminal. At this time the plasma gases (Argon) in the chamber 200 will be ionized to bombard the target 214. Hence the atoms on the target 214 will be sputtered from the target 214. Because the magnetic field of the electromagnet magnetron device 201 makes the ionized plasma gases move spirally, the deposited thin film 306a on the sidewall of the opening 304 will shift toward the direction 301 and becomes asymmetric thin film as shown in FIG. 3A.

Referring to FIG. 2B, the magnetic poles of the electromagnet magnetron device 201 are reversed in-situ and a second deposition process is then performed to complete the deposition of thin film 306. The thin film 306 includes the thin films 306a and 306b. The materials of the thin films 306a and 306b are the same. In the second deposition method the direction of current to the electromagnet magnetron device 201 is reversed so that the current becomes a reverse current making the N poles and S poles of the electromagnets 216 and 218 reversed. I.e., the S pole of the electromagnet 216 is directed upward, and the N pole of the electromagnet 218 is directed upward after magnetic pole reversion. Hence, the electromagnet magnetron device 201 has a reverse magnetic field so that the deposited thin film 306b by the second deposition process shifts toward the opposite direction 303 to form another asymmetric thin film as shown in FIG. 3B. Because the shift directions of those two thin films are opposite, the shifted thin film 306b can compensate the opposite shifted thin film 306a. Hence, the thin film 306 consisting of the thin films 306a and 306b becomes the symmetric thin film.

It should be noted that the first deposition process and the second deposition process are performed in one deposition cycle. In another embodiment, the thin film 306 is formed by performing more than one deposition cycles; i.e., the thin film 306 is formed by periodically reversing the magnetic field of the electromagnet magnetron device 201.

In addition, the thin film will have a shift based on a target life of the physical vapor deposition process. Hence one can change the magnitude of the current to adjust a magnetic field strength of the electromagnet magnetron device to reduce a shift of the thin film.

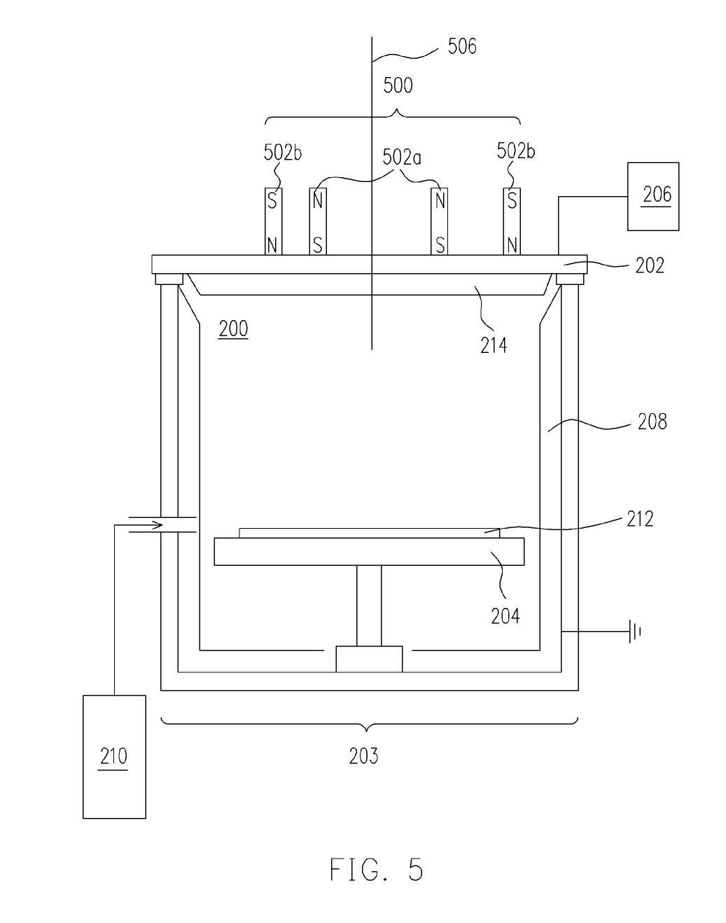

FIG. 5 is a cross-sectional view of a PVD apparatus in accordance with a second embodiment of the present invention.

Referring to FIG. 5, the PVD apparatus includes a reaction chamber 203 and a rotating magnetron device 500. The reaction chamber 203 includes the chamber 200, the target backboard 202, the plate 204, the power supply 206, the cover mask 208 and the gas supply device 210. The locations of the elements are the same as those in the first embodiment and thus will not be described again.

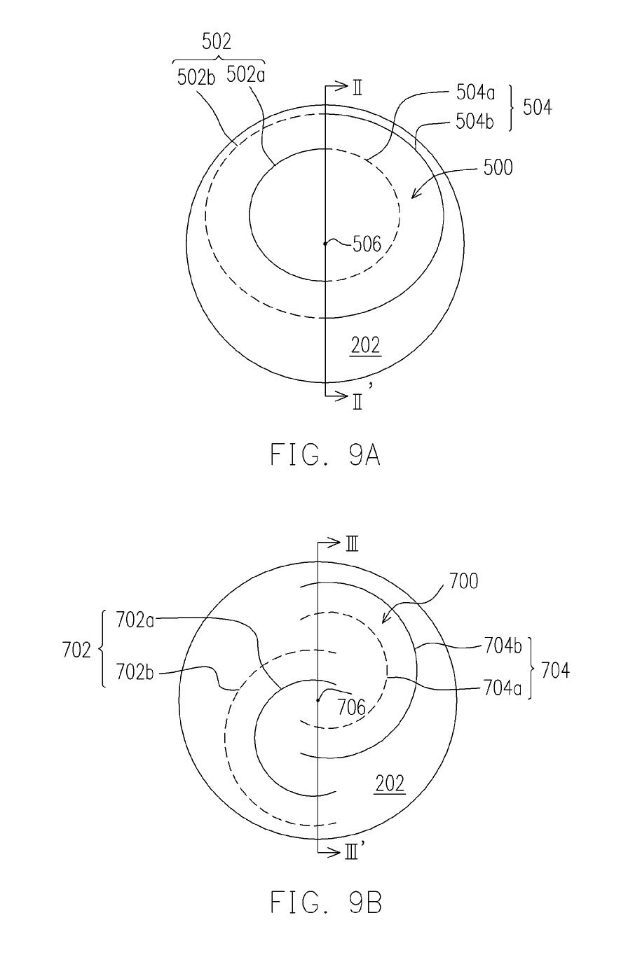

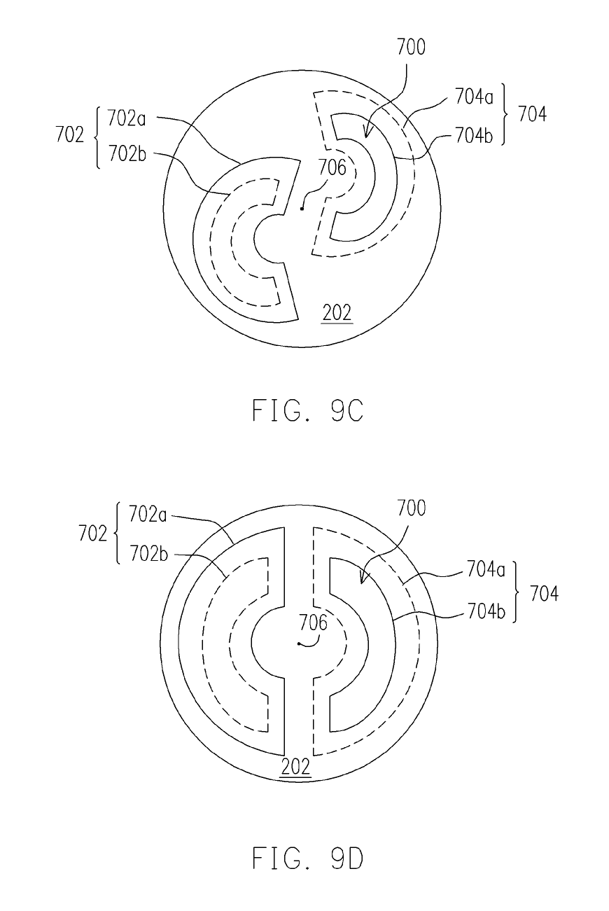

In addition, the rotating magnetron device 500 is disposed outside the chamber 200 and is above the target backboard 202. FIG. 9A is the top view of the rotating magnetron device 500. The rotating magnetron device 500 in FIG. 5 is the cross-sectional view of the rotating magnetron device 201 of FIG. 9A along the II-II′ line. In this embodiment, the rotating magnetron device 500 includes two magnet sets 502 and 504. The magnet set 502 includes two semi-circular magnets 502a and 502b. The magnet set 504 includes two semi-circular magnets 504a and 504b. The magnets 502a and 504a are disposed planarly-symmetrical to each other. In this embodiment, the symmetric plane passes perpendicularly through the central axis 506 of the target backboard 202; i.e., the plane perpendicular to the target backboard 202 along the II-II′ line is the symmetrically planar. Likewise, the magnets 502b and 504b are disposed planarly-symmetrical to each other. In addition, in this embodiment, the N poles of the magnets 502a and 504b are directed upward (S poles are directed downward); the N poles of the magnets 502b and 504a are directed downward (S poles are directed upward). It should be noted that the rotating magnetron device 500 will rotate at 360n degrees (n is a positive integer) along the central axis 506 of the target backboard 202. Hence, the magnetic field of the rotating magnetron device 500 will rotate at the same time to make the shift direction of the thin film rotate. Because after the rotating magnetron device 500 rotates every 360 degrees rotation, the asymmetric deposition will be offset, the deposited thin film on the sidewall of the opening is symmetric.

The PVD process using the above PVD apparatus will be described as follows.

Referring to FIG. 5, first the wafer 212 is disposed on the plate 204 in the chamber 200 for depositing the thin film on the surface of the wafer 212. FIG. 36A shows the cross-sectional view of the PVD process to form the thin film in the opening of the alignment mark or the overlap mark on the wafer in accordance with the first embodiment of the present invention. The alignment mark includes the Si-substrate 300 and the dielectric layer 302 on the substrate 300, and the dielectric layer 302 has an opening 304 therein.

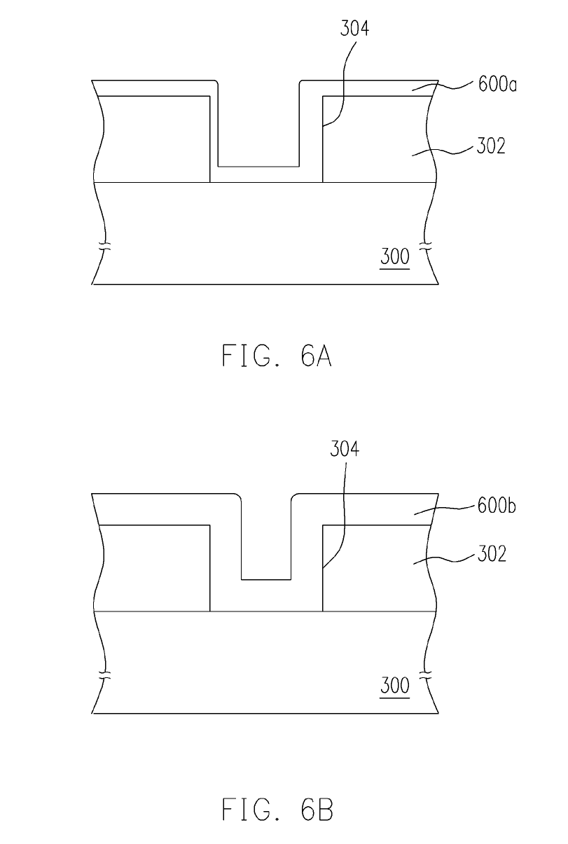

Then a deposition process is performed on the wafer 212. The rotating magnetron device 500 and the power supply 210 are activated so that the plasma gases in the chamber 200 will be ionized to bombard the target 214. Hence the atoms on the target 214 will be sputtered from the target 214. Because the magnetic field of the rotating magnetron device 500 makes the ionized plasma gases move spirally, the deposited thin film 600a on the sidewall of the opening 304 will shift toward the direction 301 and becomes asymmetric thin film as shown in FIG. 6A. However, because the rotating magnetron device 500 will rotate 360n degrees (n is a positive integral) along the central axis 506 of the target backboard 202, the rotating magnetron device 500 will rotate back to the original position after the deposition process is complete. Hence, the magnetic field of the rotating magnetron device 500 will rotate at the same time to make the shift direction of the thin film rotate so that the deposited thin film 600b on the sidewall of the opening 304 is symmetric as shown in FIG. 6B.

It should be noted that although in the second embodiment the rotating magnetron device 500 of FIG. 9A is used to illustrate the present invention, it cannot be used to limit the scope of the present invention. I.e., once the magnet sets of the rotating magnetron device 500 are disposed planarly-symmetrical on the target backboard 202, the symmetric thin film 600b on the sidewall of the opening 304 as shown in FIG. 6B will be obtained.

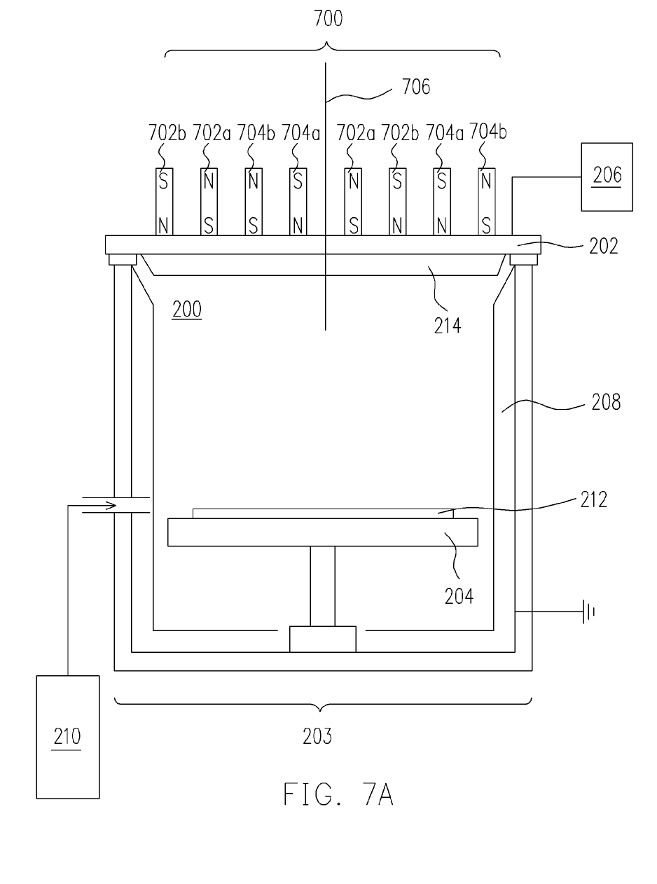

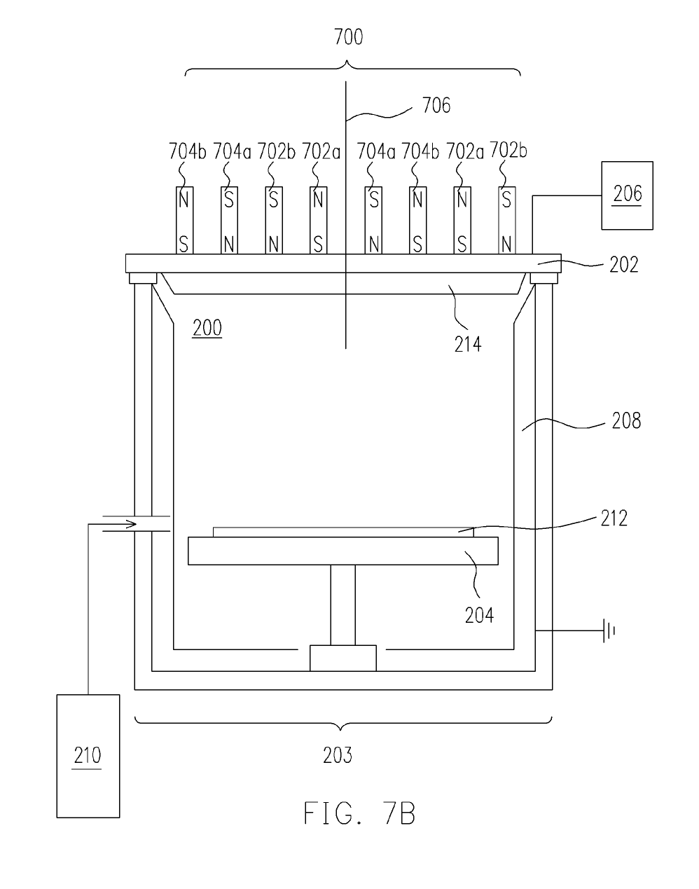

FIG. 7A is a cross-sectional view of the PVD apparatus in accordance with a third embodiment of the present invention.

Referring to FIG. 7A, the PVD apparatus includes the reaction chamber 203 and a rotating magnetron device 700. The reaction chamber 203 includes the chamber 200, the target backboard 202, the plate 204, the power supply 206, the cover mask 208 and the gas supply device 210. The locations of the elements are the same as those in the first embodiment and thus will not be described again.

In addition, the rotating magnetron device 700 is disposed outside the chamber 200 and is above the target backboard 202. FIG. 9B is the top view of the rotating magnetron device 700. The rotating magnetron device 700 in FIG. 7A is the cross-sectional view of the rotating magnetron device 201 of FIG. 9B along the III-III line. In this embodiment, the rotating magnetron device 700 includes two magnet sets 702 and 704. The magnet set 702 includes two semi-circular magnets 702a and 702b. The magnet set 704 includes two semi-circular magnets 704a and 704b. The magnets 702a and 704a are disposed axially-symmetrical to each other. In this embodiment, the symmetric axis passes perpendicularly through the central axis 706 of the target backboard 202. Likewise, the magnets 702b and 704b are disposed axially-symmetrical to each other. In addition, in this embodiment, the N poles of the magnets 702a and 704b are directed upward (S poles are downward); the N poles of the magnets 702b and 704a are directed downward (S poles are directed upward). It should be noted that the rotating magnetron device 700 will rotate 180n degrees (n is a positive integer) along the central axis 706 of the target backboard 202. Hence, the magnetic field of the rotating magnetron device 700 will rotate at the same time to make the shift direction of the thin film rotate. Because after the rotating magnetron device 700 rotates every 180 degrees the asymmetric deposition will be offset, the deposited thin film on the sidewall of the opening is symmetric.

It should be noted in addition to the disposition of the magnet sets 702 and 704 as shown in FIG. 9B, the magnet sets 702 and 704 of the rotating magnetron device 700 can be comprised of horse-shoe magnets 702a, 702b, 704a and 704b to form the disposition as shown in FIGS. 9C and 9D. Of course, other dispositions also can be used if the magnet sets are disposed axially-symmetrical on the target backboard 202 so that the deposited thin film on the sidewall of the opening is symmetric.

The PVD process using the above PVD apparatus will be described as follows.

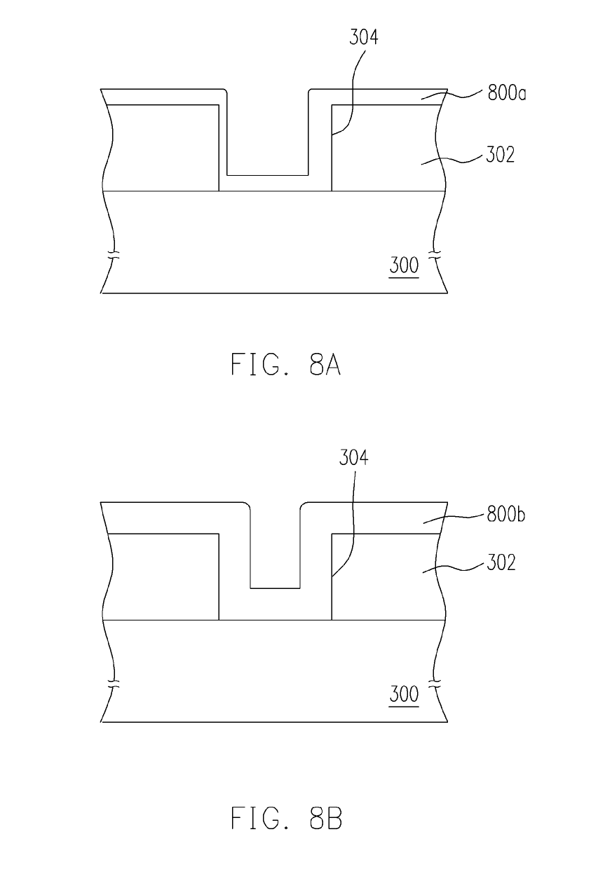

Referring to FIG. 7A, first the wafer 212 is disposed on the plate 204 in the chamber 200 for depositing the thin film on the surface of the wafer 212. FIG. 8A shows the cross-sectional view of the PVD process for forming the thin film in the opening of the alignment mark or the overlap mark on the wafer in accordance with the first embodiment of the present invention. The alignment mark or the overlap mark includes the Si-substrate 300 and the dielectric layer 302 on the substrate 300, and the dielectric layer 302 has an opening 304 therein.

Then the deposition process is performed on the wafer 212. The rotating magnetron device 700 and the power supply 210 are activated so that the plasma gases in the chamber 200 will be ionized to bombard the target 214. Hence the atoms on the target 214 will be sputtered from the target 214. Because the magnetic field of the rotating magnetron device 700 makes the ionized plasma gases move spirally, the deposited thin film 800a on the sidewall of the opening 304 will shift toward the direction 301 and becomes asymmetric thin film as shown in FIG. 8A. However, because the rotating magnetron device 800 will rotate 180n degrees (n is a positive integral) along the central axis 706 of the target backboard 202, the rotating magnetron device 700 will rotate back to the original position of the magnet set 704 after the deposition process is complete, and the magnet set 704 will go back to the original position of the magnet set 702 (as shown in FIG. 7B). Hence, the magnetic field of the rotating magnetron device 700 will rotate at the same time to make the shift direction of the thin film rotate so that the deposited thin film 800b on the sidewall of the opening 304 is symmetric as shown in FIG. 8B.

It should be noted that although in the third embodiment the rotating magnetron device 700 of FIG. 9B is used to illustrate the present invention, it cannot be used to limit the scope of the present invention. I.e., the embodiment of using the magnet sets of the rotating magnetron device 700 disposed axially-symmetric on the target backboard 202 to obtain the symmetric thin film 800b on the side-wall of the opening 304 as shown in FIG. 8B cannot be used to limit the scope of the present invention.

In light of the above, the present invention has the following advantages:
1. Because during the PVD process the magnetic poles of the electromagnet magnetron device reversed in in-situ to reverse the shift direction of the asymmetric deposition of the thin film, the possibility of asymmetric deposition of the thin film on the sidewalls of the opening can be effectively reduced.
2. Because during the deposition process the rotating magnetron device rotates to rotate the shift direction of the asymmetric deposition of the thin film, the possibility of asymmetric deposition of the thin film on the sidewalls of the opening can be effectively reduced.
3. By applying the present invention to the metal line defining process, unlike the prior art, it does not have to individually adjust the parameters to compensate the shift of the alignment mark or the overlap mark generated during photolithographic process. Hence, the process can be much simpler.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

1. A physical vapor deposition apparatus, comprising:
a reaction chamber; and
an electromagnet magnetron device, disposed above and outside said reaction chamber, wherein when performing a physical vapor deposition process, magnetic poles of said electromagnet magnetron device are reversed in-situ.

2. The apparatus of claim 1, wherein said electromagnet magnetron device includes a plurality of magnets.

3. The apparatus of claim 1, wherein said reaction chamber includes:
a chamber;
a target backboard, at the top of said chamber; and
a plate, disposed at the bottom of said reaction chamber.

4. A physical vapor deposition process, comprising:
providing a chamber and an electromagnet magnetron device disposed above and outside said reaction chamber;
starting said electromagnet magnetron device to perform a first deposition process; and
reversing magnet poles of said electromagnet magnetron device to perform a second deposition process to deposit a thin film.

5. The process of claim 4, wherein said first deposition process and said second deposition process are implemented in one deposition cycle, and said thin film is formed by more than one of said deposition cycle.

6. The process of claim 4, further comprising a step of changing a magnitude of a current to adjust a magnetic field strength of said electromagnet magnetron device to reduce a shift of said thin film based on a target life of said physical vapor deposition process.

7. The process of claim 4, wherein said electromagnet magnetron device includes a plurality of magnets.

8. A physical vapor deposition apparatus, comprising:
a reaction chamber; and
a rotating magnetron, device disposed above and outside said reaction chamber, said rotating magnetron device including at least two magnet sets, said magnet sets being axially-symmetric or planarly-symmetric to each other and magnetic pole of said magnet sets being disposed opposite to each other.

9. The apparatus of claim 8, wherein said reaction chamber includes:
a chamber;
a target backboard, at the top of said chamber; and
a plate disposed at the bottom of said reaction chamber.

10. The apparatus of claim 9, wherein an axis of said axially-symmetrically disposed magnet sets or a plane of said planarly-symmetrically disposed magnet sets passes through a central axis of said target backboard, and when performing a physical vapor deposition process, said rotating magnetron device rotates along said central axis.

11. The apparatus of claim 8, wherein one of said two magnet sets includes a first magnet and a second magnet; the other of said two magnet sets includes a third magnet and a fourth magnet; said first magnet and said third magnet are disposedaxially-symmetrical to each other; said second magnet and said fourth magnet are disposedaxially-symmetrical to each other; a first magnetic pole of said first magnet and said fourth magnet and a first magnetic pole of said second magnet and said third magnet are disposed opposite each other.

12. The apparatus of claim 8, wherein one of said two magnet sets includes a first magnet and a second magnet; the other of said two magnet sets includes a third magnet and a fourth magnet; said first magnet and said third magnet are disposed planarly-symmetrical to each other; said second magnet and said fourth magnet are disposed planarly-symmetrical to each other; a first magnetic pole of said first magnet and said fourth magnet, and a first magnetic pole of said second magnet and said third magnet are disposed opposite to each other.

13. A physical vapor deposition process, comprising:
providing a chamber and a rotating magnetron device disposed above and outside said reaction chamber, said rotating magnetron device including at least two magnet sets, said magnet sets being disposed axially-symmetrical or planarly-symmetrical and magnetic pole of said magnet sets being disposed opposite; and
starting said rotating magnetron device to perform a deposition process, and rotating said rotating magnetron device during said deposition process.

14. The process of claim 13, wherein said magnet sets are disposed axially-symmetrical, and said rotating magnetron device rotates by 180n degrees during said deposition process, wherein said n is a positive integer.

15. The process of claim 13, wherein said magnet sets are disposed axially-symmetrical, and said rotating magnetron device rotates by 360n degrees during said deposition process, wherein said n is a positive integer.
